(19) United States
(12) Patent Application Publication
(10) Pub. No.: US 2005/0161726 A1
(43) Pub. Date: Jul. 28, 2005

(54) Capacitor of a semiconductor device, memory device including the same and method of munufacturing the same

(76) Inventors: Sang-min Shin, Seoul (KR); June-mo Koo, Seoul (KR); Suk-pil Kim, Yongin-si (KR); Choong-rae Cho, Gimhae-si (KR)

Correspondence Address: LEE & MORSE, P.C., 1101 WILSON BOULEVARD, SUITE 2000, ARLINGTON, VA, 22209, US

(21) Appl. No.: 11/042,111

(22) Filed: Jan. 26, 2005

(30) Foreign Application Priority Data
Jan. 26, 2004 (KR) 10-2004-0004681

(51) Int. Cl. H01L 29/76

(52) U.S. Cl. 257/306

(57) ABSTRACT

In a capacitor, a memory device including the capacitor, and a method of manufacturing the capacitor, the capacitor includes a lower electrode comprising a single layer of one selected from the group including a noble metal alloy and an oxide thereof, a dielectric film formed on the lower electrode, and an upper electrode formed on the dielectric film.

### BACKGROUND OF THE INVENTION

1. Field of the Invention

The present invention relates to a semiconductor device and a method of manufacturing the same. More particularly, the present invention relates to a capacitor having increased reproducibility, reliability, and yield, a memory device including the capacitor, and a method of manufacturing the capacitor.

2. Description of the Related Art

A capacitor of a semiconductor device includes a lower electrode, a dielectric film, and an upper electrode, and is commonly used as a data storage medium for a semiconductor memory device, such as a dynamic random access memory (DRAM).

DRAM and static random access memory (SRAM) offer advantages of higher integration densities and faster data processing speeds than nonvolatile memory devices, such as flash memory, but also have a disadvantage of losing stored data when power is turned off.

Therefore, memory devices that have the advantages of volatile memory, such as DRAM and SRAM, and the advantages of nonvolatile memory, such as flash memory, have been developed. One of such memory devices is a ferroelectric random access memory (FRAM).

An FRAM, which is a nonvolatile memory device that can store and reproduce data, offers a combination of advantages of an SRAM, such as fast reading and writing, with an advantage of an erasable programmable read-only memory (EPROM).

The characteristics of the FRAM result from a ferroelectric capacitor included in the FRAM (hereinafter, a ferroelectric capacitor). The ferroelectric capacitor includes a lower electrode, a dielectric film, and an upper electrode, which is similar to a general semiconductor capacitor. However, the properties of the dielectric film of a ferroelectric capacitor are different from the properties of the dielectric film of a general semiconductor capacitor.

More specifically, the dielectric film of a ferroelectric capacitor has remnant polarization after power is turned off, unlike a general semiconductor capacitor. This remnant polarization remains until an electric field changes a direction of polarity. The polarization is the key factor for the FRAM being a nonvolatile memory device.

Configurations of an FRAM and a DRAM may be identical. Accordingly, a process of manufacturing a DRAM can be applied in the manufacture of an FRAM. As a result, more attention has been devoted to FRAM than to other nonvolatile memory devices.

In the capacitor included in the FRAM, since a ferroelectric film, e.g., a lead zirconate titanate (PZT) film, is used as a dielectric film, etching-resistive electrodes that are not affected by a process of forming the ferroelectric film are used as the lower and upper electrodes. For example, when a PZT film is used, the lower electrode may be an iridium (Ir) electrode, and the upper electrode may be an iridium (Ir) electrode or an electrode composed of an oxide of Ir.

However, a conventional ferroelectric capacitor has the following drawbacks. First, the PZT film is formed by a Metal Organic Chemical Vapor Deposition (MOCVD) method, but a process range, i.e., a process window, for forming the PZT film is narrow. Second, the PZT film has a very rough surface. Third, there is a large leakage current at an interface between the lower electrode and the PZT film.

### SUMMARY OF THE INVENTION

The present invention is therefore directed to a capacitor of a semiconductor device, a memory device including the capacitor, and a method of manufacturing the capacitor, which substantially overcome one or more of the problems due to the limitations and disadvantages of the related art.

It is a feature of an embodiment of the present invention to provide a capacitor having increased reproducibility, reliability, and yield.

It is another feature of an embodiment of the present invention to provide a capacitor that can be processed at a low temperature, has improved characteristics, and has a wide process window.

It is still another feature of an embodiment of the present invention to provide a memory device including the capacitor.

It is yet another feature of an embodiment of the present invention to provide a method of manufacturing the capacitor.

At least one of the above and other features and advantages of the present invention may be realized by providing a capacitor including a lower electrode including a single layer of one selected from the group including a noble metal alloy and an oxide thereof, a dielectric film formed on the lower electrode, and an upper electrode formed on the dielectric film.

The capacitor may further include a noble metal layer, on which the lower electrode is formed. The noble metal layer may be an iridium layer. The lower electrode may include an alloy including platinum and iridium, and a thickness of the lower electrode may be in a range of between about 10 to about 30 nm.

The lower electrode may include an alloy including platinum and iridium.

The dielectric film may be a PZT film. The PZT film may include one selected from the group including a rare earth element and a silicate.

The lower electrode may include an alloy including platinum and iridium, and a thickness of the lower electrode may be in a range of between about 10 to about 100 nm.

The lower electrode may include an oxide of an alloy including platinum and iridium.

At least one of the above and other features and advantages of the present invention may be realized by providing a memory device including a substrate, a transistor formed on the substrate, and a capacitor connected to the transistor, wherein the capacitor includes a lower electrode including a single layer of one selected from the group including a noble metal alloy and an oxide thereof, a dielectric film formed on the lower electrode, and an upper electrode formed on the dielectric film.

The noble metal alloy may include platinum and iridium.

The noble metal alloy oxide may include an oxide of an alloy including platinum and iridium.

The memory device may further include a noble metal layer, on which the lower electrode is formed. The noble metal layer may be an iridium layer.

The memory device may further include a connection unit for connecting the capacitor to the transistor and a diffusion barrier film interposed between the connection unit and the lower electrode. The diffusion barrier film may be selected from the group including a TiAlN film and a TiN film.

At least one of the above and other features and advantages of the present invention may be realized by providing a method of manufacturing a capacitor including forming a lower electrode including a single layer of one selected from the group including a noble metal alloy and an oxide thereof and sequentially stacking the lower electrode, a dielectric film, and an upper electrode.

The method may further include forming the lower electrode on a noble metal layer.

The dielectric film may be a PZT film. Forming the PZT film may include using one of chemical vapor deposition (CVD), atomic layer deposition (ALD), and sputtering. The method may further include doping the PZT film with a rare earth element. The method may further include adding a silicate to the PZT film.

Forming the lower electrode may include using multi-targets or an alloy target.

The noble metal alloy may include platinum and iridium.

Forming the lower electrode may further include forming a noble metal alloy and oxidizing the noble metal alloy.

The lower electrode according to an embodiment of the present invention acts as a strong diffusion barrier, reducing a leakage current at an interface between the lower electrode and the ferroelectric film. Also, a crystal nucleus of the ferroelectric film can be easily grown and surface roughness of the ferroelectric film can be reduced. Further, since a wide process window for the ferroelectric film can be secured, the ferroelectric film can be formed under a variety of process conditions.

Since a strong diffusion barrier function and a wide process window are obtained, reproducibility, reliability, and yield of the capacitor can be increased. In addition, physical properties, such as fatigue characteristics and a data retention characteristic, can be improved.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 illustrates a cross-sectional view of a capacitor of a semiconductor device according to an embodiment of the present invention;

FIG. 2 illustrates a cross-sectional view of a memory device including the capacitor shown in FIG. 1;

FIG. 3A is a scanning electron microscope (SEM) image of a surface of a dielectric film when a lower electrode and a dielectric film are an Ir film and a PZT film, respectively, in a specimen capacitor, i.e., a capacitor for experiment, formed identical to the capacitor shown in FIG. 1;

FIG. 3B is an SEM image of a cross-section of a lower electrode and a dielectric film of the capacitor shown in FIG. 3A;

FIG. 4A is an SEM image of a surface of a dielectric film when a lower electrode and a dielectric film in an experimental capacitor are an Ir3Pt1 and a PZT film, respectively;

FIG. 4B is an SEM image of a cross-section of the lower electrode and the dielectric film of the capacitor shown in FIG. 4A;

FIG. 5A is an SEM image of a surface of a dielectric film when a lower electrode and a dielectric film in an experimental capacitor are an IrPt and a PZT film, respectively;

FIG. 5B is an SEM image of a cross-section of the lower electrode and the dielectric film of the capacitor shown in FIG. 5A;

FIG. 6A is an SEM image of a surface of a dielectric film when a lower electrode and a dielectric film in an experimental capacitor are an IrPt3 and a PZT film, respectively;

FIG. 6B is an SEM image of a cross-section of the lower electrode and the dielectric film of the capacitor shown in FIG. 6A;

FIG. 7A is an SEM image of a surface of a dielectric film when a lower electrode and a dielectric film in an experimental capacitor are a platinum (Pt) and a PZT film, respectively;

FIG. 7B is an SEM image of a cross-section of the lower electrode and the dielectric film of the capacitor shown in FIG. 7A;

FIG. 8 is an SEM image illustrating a surface roughness of a lower electrode when the lower electrode in an experimental capacitor is an Ir electrode;

FIG. 9 is an SEM image illustrating a surface roughness of a lower electrode when the lower electrode in an experimental capacitor is an Ir3Pt1 electrode;

FIG. 10 is an SEM image illustrating a surface roughness of a lower electrode when the lower electrode in an experimental capacitor is an IrPt electrode;

FIG. 11 is an SEM image illustrating a surface roughness of a lower electrode when the lower electrode in an experimental capacitor is an Ir1Pt3 electrode;

FIG. 12 is an SEM image illustrating a surface roughness of a lower electrode when the lower electrode in an experimental capacitor is a Pt electrode;

FIG. 13 is an SEM image illustrating a surface roughness of a dielectric film when a lower electrode and the dielectric film in an experimental capacitor are an Ir electrode and a PZT film, respectively;

FIG. 14 is an SEM image illustrating a surface roughness of a dielectric film when a lower electrode and the dielectric film in an experimental capacitor are an Ir3Pt1 electrode and a PZT film, respectively;

FIG. 15 is an SEM image illustrating a surface roughness of a dielectric film when a lower electrode and the dielectric film in an experimental capacitor are an IrPt electrode and a PZT film, respectively;

FIG. 16 is an SEM image illustrating a surface roughness of a dielectric film when a lower electrode and the dielectric film in an experimental capacitor are an Ir1Pt3 electrode and a PZT film, respectively;

FIG. 17 is an SEM image illustrating a surface roughness of a dielectric film when a lower electrode and the dielectric film in an experimental capacitor are a Pt electrode and a PZT film, respectively;

FIG. 18 is a graph illustrating surface roughness of PZT films according to several lower electrodes of experimental capacitors;

FIG. 19 is a graph illustrating polarization characteristics according to several lower electrodes of experimental capacitors;

FIG. 20 is a graph illustrating fatigue characteristics according to several lower electrodes of experimental capacitors; and

FIG. 21 is a graph illustrating remnant polarization ratios of experimental capacitors.

### DETAILED DESCRIPTION OF THE INVENTION

Korean Patent Application No. 10-2004-0004681, filed on Jan. 26, 2004, in the Korean Intellectual Property Office, and entitled: “Capacitor of Semiconductor Device, Memory Device Comprising the Same and Method of Manufacturing the Same,” is incorporated by reference herein in its entirety.

The present invention will now be described more fully hereinafter with reference to the accompanying drawings, in which exemplary embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. In the drawing figures, the dimensions of layers and regions are exaggerated for clarity of illustration. It will be understood that when an element such as a layer, region or substrate is referred to as being “on” another element, it can be directly on the other element or intervening elements may also be present. Similarly, it will be understood that when an element is referred to as being “under” another element, it can be directly under, and one or more intervening elements may also be present. In addition, it will also be understood that when an element is referred to as being “between” two elements, it can be the only element between the two elements, or one or more intervening elements may also be present. Like reference numerals and characters refer to like elements throughout the specification and drawing figures.

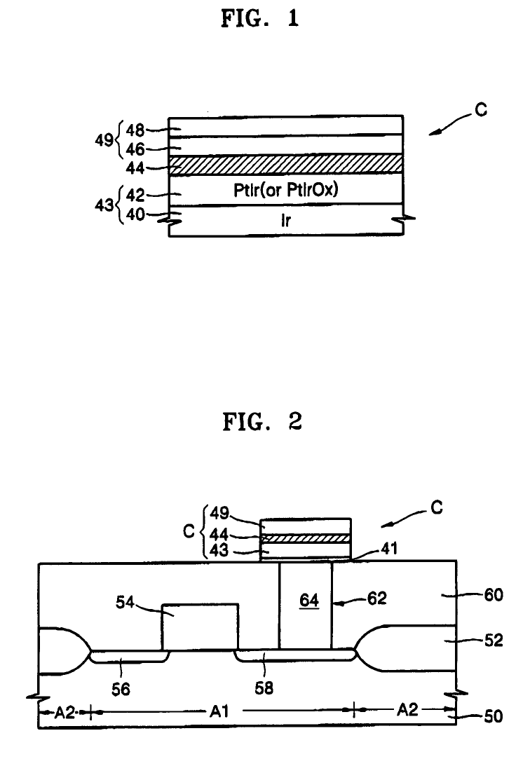

FIG. 1 illustrates a cross-sectional view of a capacitor of a semiconductor device according to an embodiment of the present invention. FIG. 2 illustrates a cross-sectional view of a memory device including the capacitor shown in FIG. 1.

Referring to FIG. 1, a capacitor C of a semiconductor device according to an embodiment of the present invention includes a lower electrode 43, a dielectric film 44, and an upper electrode 49. The lower electrode 43 may be a single layer or a double layer. When the lower electrode 43 is a double layer, as illustrated in FIG. 1, the lower electrode 43 may include first and second lower electrodes 40 and 42 stacked sequentially. The first lower electrode 40 may be an etching-resistive metal electrode, e.g., an iridium (Ir) electrode. When the first lower electrode 40 is an Ir electrode, a thickness of the first lower electrode 40 may be in a range of between about 30 to about 70 nm. The second lower electrode 42 may be an alloy electrode, e.g., a noble metal alloy electrode. The second lower electrode 42 may be a noble metal alloy electrode, e.g., a PtIr electrode. When the second lower electrode 42 is an alloy electrode including platinum (Pt) and iridium (Ir), the content of Pt can be between about 5 to about 40% of the total alloy electrode based on atom concentration. Alternatively, the second lower electrode 42 may be an alloy oxide electrode, e.g., a noble metal alloy oxide electrode. The second lower electrode 42 may preferably be a PtIrOₓ, where 0.5<X≦2, electrode. When the second lower electrode 42 is an alloy electrode including Pt and Ir, a thickness of the second lower electrode 42 may be in a range of between about 10 to about 30 nm. When the second lower electrode 42 is an alloy oxide electrode including Pt and Ir, a thickness of the second lower electrode 42 may be in a range of between about 10 to about 30 nm.

When the lower electrode 43 is a single layer, the lower electrode 43 may include only the second lower electrode 42. In this arrangement, the second lower electrode 42 may be formed in accordance with the above descriptions.

The dielectric film 44 is a ferroelectric film, and may preferably be a Pb(Zr_{X}Ti_{1-X})O₃ (PZT) film or another ferroelectric film, such as a (Sr₁₋ₓPbₓ)TiO₃ (SPT) film. When the dielectric film 44 is a PZT film, the dielectric film 44 may be a film doped with a rare earth element, e.g., lanthanum, and may contain a predetermined additive, e.g., a silicate, such as Bi₂SiO₅ (BSO). The additive and dopant may vary according to the ferroelectric film used as the dielectric film 44. When the lower electrode 43 is an Ir electrode and a PtIr (or PtIrOₓ) electrode stacked sequentially and the dielectric film 44 is a PZT film, a thickness of the dielectric film 44 may be in a range of between about 30 nm to about 150 nm. The thickness of the dielectric film 44 can vary according to the material used to form the lower electrode 43.

The upper electrode 49 may be a single layer or a double layer. When the upper electrode 49 is a double layer, it may include first and second upper electrodes 46 and 48 stacked sequentially. The first upper electrode 46, formed on the dielectric film 44, may be an IrOₓ electrode, and the second upper electrode 48, formed on the first upper electrode 46, may be an Ir electrode.

When the upper electrode 49 is a single layer, the upper electrode 49 may include only the first upper electrode 46, e.g., the IrOₓ electrode. In this arrangement, the first upper electrode 46 may be formed in accordance with the above descriptions.

A memory device according to an embodiment of the present invention, in which the memory device includes the capacitor C according to an embodiment of the present embodiment, will now be described.

Referring to FIG. 2, the memory device includes a substrate 50, e.g., a silicon wafer, and a transistor including a gate stack 54 formed on an active region A1 of the substrate 50. Source and drain regions 56 and 58 are formed in the substrate 50 in the active region A1. The transistor is electrically separated from an adjacent transistor by a field oxide film 52 formed on the substrate 50 in a field region A2. An interlayer insulating layer 60, e.g., a borophosphosilicate glass (BPSG) layer, covering the transistor is formed on the substrate 50. A contact hole 62 exposing the drain region 58 is formed through the interlayer insulating layer 60, and the contact hole 62 is filled with a conductive plug 64. The conductive plug 64 may be a tungsten plug or another conductive plug, e.g., a polysilicon plug, having a low contact resistance with the drain region 58. An additional film for reducing contact resistance between the conductive plug 64 and the drain region 58 may be formed. Alternatively, a region of the drain region 58 that contacts the conductive plug 64 may be doped to reduce contact resistance.

A diffusion barrier film 41 covering the conductive plug 64 may be formed on the interlayer insulating layer 60. The diffusion barrier film 41 may be a titanium aluminum nitride (TiAlN) film or another material film, e.g., a titanium nitride (TiN) film. The capacitor C according to an embodiment of the present invention may be formed on the diffusion barrier film 41. The lower electrode 43 of the capacitor C, as illustrated in FIG. 1, may include the first and second lower electrodes 40 and 42, and the first lower electrode 40 can act as a diffusion barrier. Therefore, the diffusion barrier film 41 is optional.

Next, experiments performed to determine physical properties of the capacitor C will be described. For the experiments, first through fifth capacitors C1 through C5 were prepared having identical configurations except with respect to the lower electrode.

More specifically, the dielectric film 44 of each of the first through fifth capacitors C1 through C5 are PZT films, and the upper electrodes were formed by sequentially stacking an IrOₓ film and an Ir film.

Regarding the varying lower electrode, the lower electrode 43 of the first capacitor C1 is an Ir electrode, the lower electrode 43 of the second capacitor C2 is an alloy (Ir3Pt1) electrode, in which Ir and Pt are mixed in a ratio of 75:25, the lower electrode 43 of the third capacitor C3 is an alloy (Ir1Pt1) electrode, in which Ir and Pt are mixed in a ratio of 50:50, the lower electrode 43 of the fourth capacitor C4 is an alloy (Ir1Pt3) electrode, in which Ir and Pt are mixed in a ratio of 25:75, and the lower electrode 43 of the fifth capacitor C5 is a Pt electrode.

The lower electrode 43 of each of the first through fifth capacitors C1 through C5 is formed using a co-sputter to a thickness of approximately 1000 Å. A mixing ratio of the Ir and the Pt in the lower electrode 43 of each of the second through fourth capacitors C2 through C4 is controlled by controlling the power of the co-sputter.

Table 1 summarizes kinds of lower electrodes, the mixing ratios, and methods of deposition of the lower electrodes for each of the first through fifth capacitors C1 through C5.

TABLE 1

| | Kind of Lower | | Method of |
|---|---|---|---|
| Capacitor | Electrode | Ir:Pt | Deposition |
| C1 | Ir | 100:0 | Co-sputter |
| C2 | Ir3Pt1 | 75:25 | Co-sputter |
| C3 | Ir1Pt1 | 50:50 | Co-sputter |
| C4 | Ir1Pt3 | 25:75 | Co-sputter |
| C5 | Pt | 0:100 | Co-sputter |

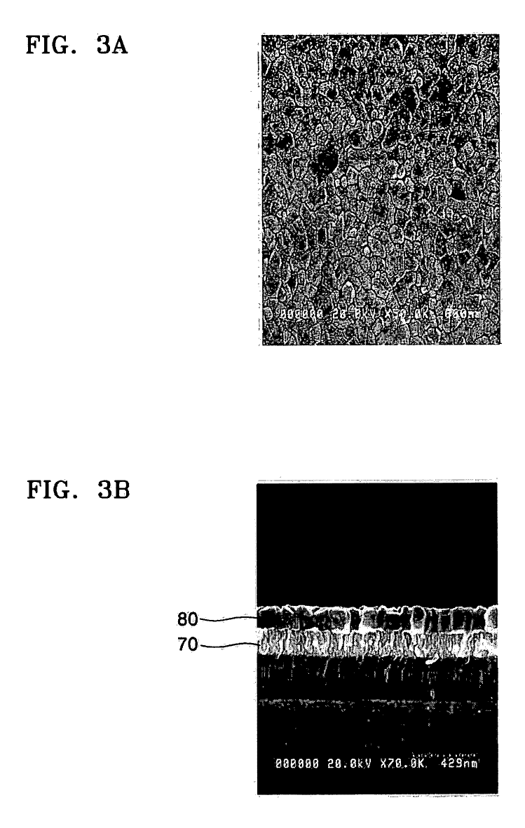

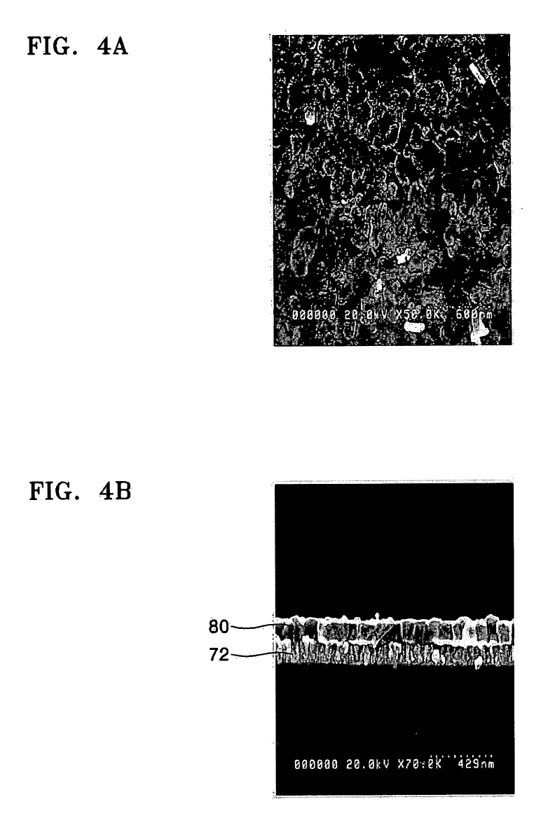

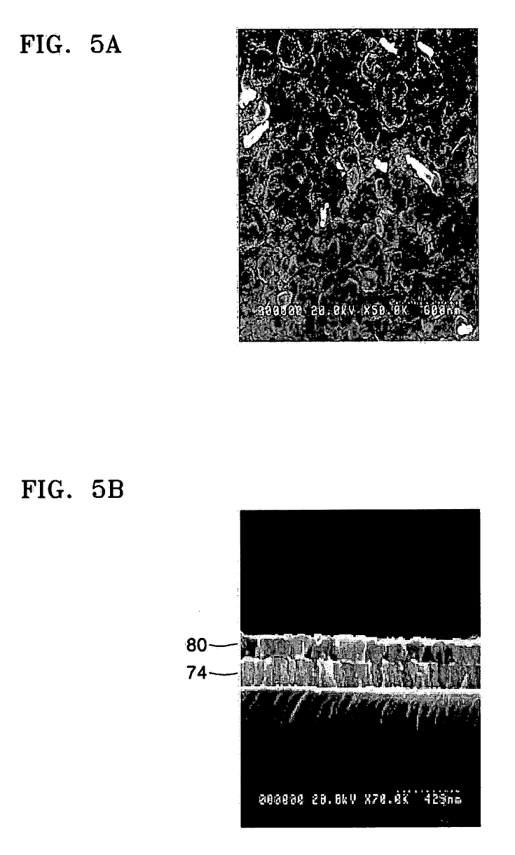

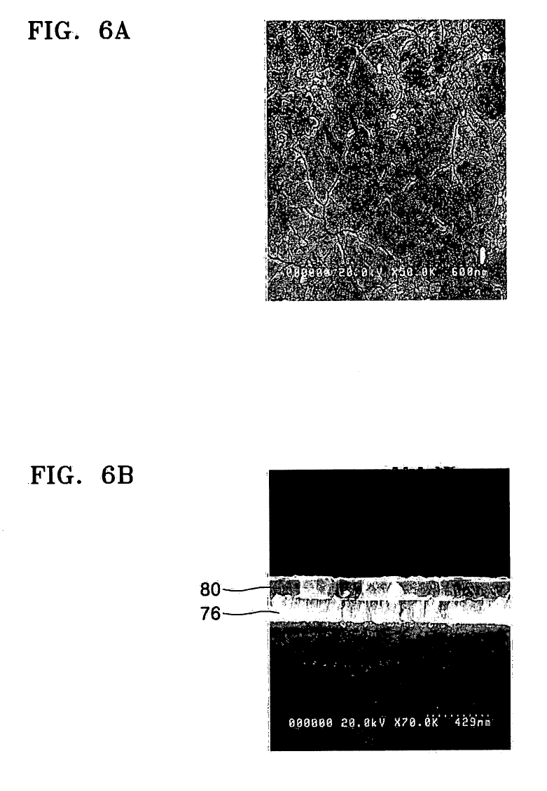

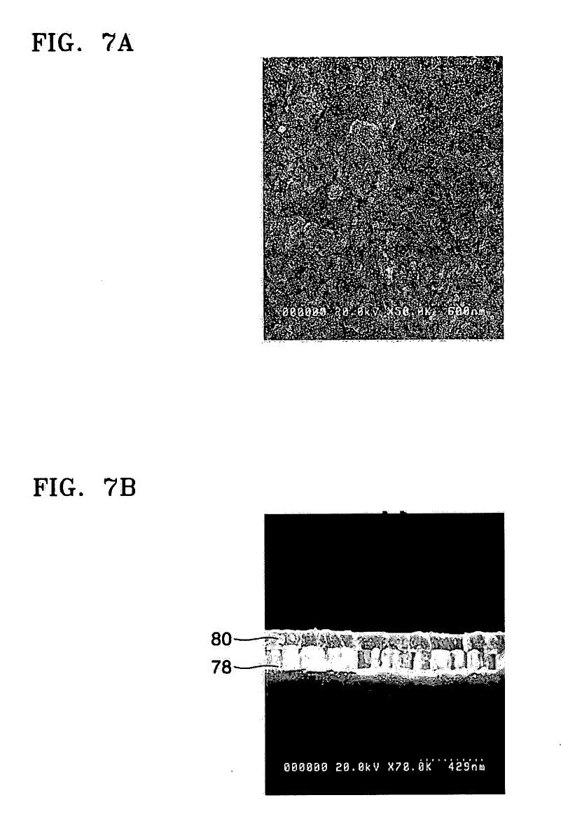

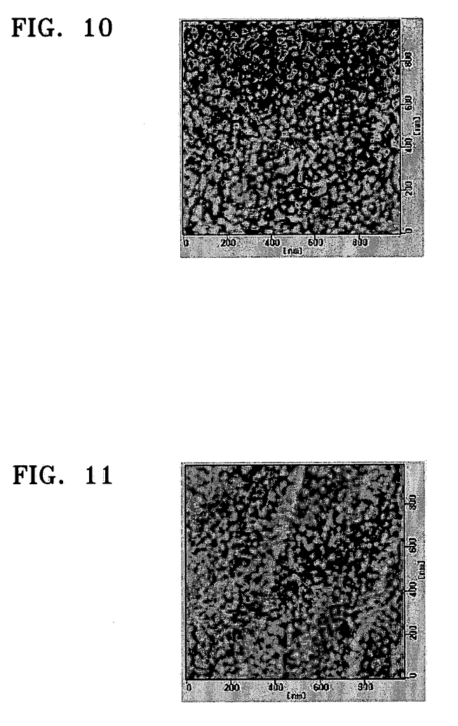

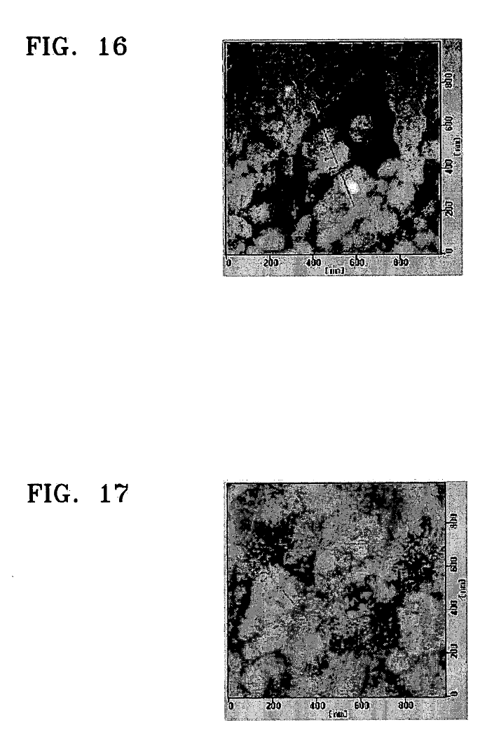

From these experiments, a surface roughness of the lower electrode 43 and the ferroelectric film, polarization characteristics of the ferroelectric film, and characteristics of fatigue were measured. Scanning electron microscope (SEM) images illustrating the capacitors are shown in FIGS. 3 through 20.

FIGS. 3A, 4A, 5A, 6A, and 7A are SEM images illustrating a surface of the dielectric film, i.e., the PZT film, of the first through fifth capacitors C1 through C5, respectively. FIGS. 3B, 4B, 5B, 6B, and 7B are SEM images illustrating a cross-section of the lower electrode and the dielectric film of the first through fifth capacitors C1 through C5, respectively. Reference numerals 70, 72, 74, 76, and 78 in FIGS. 3B, 4B, 5B, 6B, and 7B, represent the lower electrodes composed of Ir, Ir3Pt1, IrPt, IrPt3, and Pt, respectively. Reference numeral 80 represents the PZT film.

When FIGS. 3A, 4A, 5A, 6A, and 7A are compared, and FIGS. 3B, 4B, 5B, 6B, and 7B are compared, it may be seen that as the Pt content in the lower electrode increases, a grain boundary of the PZT film becomes fainter. From this result, when the lower electrode is an alloy electrode that includes Ir and Pt, it is seen that the PZT film has a greater lateral growth rate than a vertical growth rate.

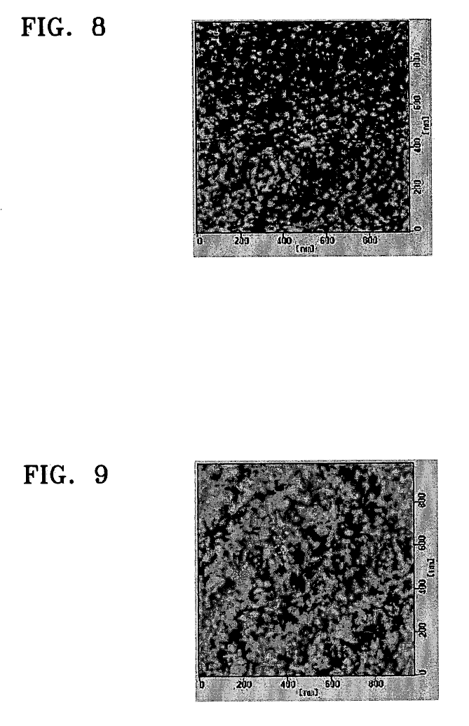

FIGS. 8 through 12 are SEM images illustrating surface roughness of the lower electrodes of the first through fifth capacitors C1 through C5, respectively.

Referring to FIGS. 8 through 12, as the Pt content in the lower electrode increases, the granular size of the lower electrode also increases.

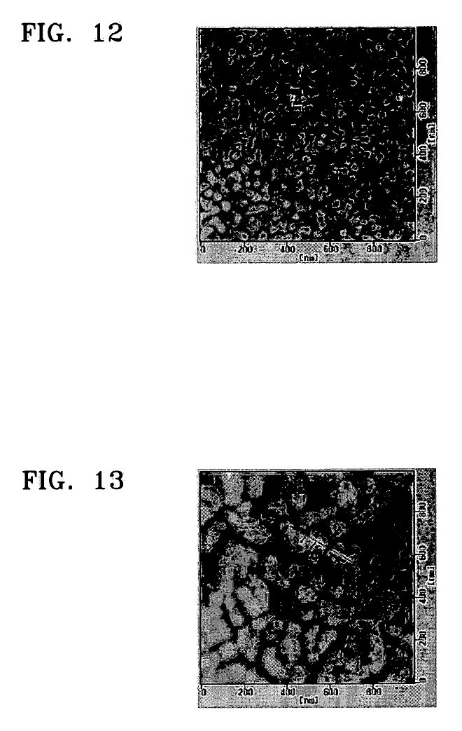

More specifically, when the lower electrode is composed of only Ir, as shown in FIG. 8, the granular size is about 16 nm, but when the lower electrode is composed of Ir—Pt, as shown in FIGS. 9, 10, and 11, the granular size is about 19 nm, and when the lower electrode is composed of only Pt, as shown in FIG. 12, the granular size increases to about 35 nm.

With further reference to FIGS. 8 through 12, the surface roughness of the lower electrode increases as the Pt content in the lower electrode increases.

More specifically, when the lower electrode is composed of only Ir, as shown in FIG. 8, the surface roughness is about 0.37 nm, when the lower electrode is composed of Ir—Pt, as shown in FIGS. 9, 10, and 11, the roughness is about 0.53 nm, and when the lower electrode is composed of only Pt, as shown in FIG. 12, the roughness is about 1.15 nm.

Thus, as the Pt content of the lower electrode increases, both the grain size and the surface roughness of the lower electrode increase and the shape of the grain becomes a definite form.

FIGS. 13 through 17 are SEM images illustrating a surface roughness of the PZT film deposited on the lower electrode of the first through fifth capacitors C1 through C5.

Referring to FIGS. 13 through 17, as the Pt content of the lower electrode increases, a black portion in a grain boundary of the PZT film gradually disappears. This is a result of a decrease in the height difference between the highest point of a grain and the lowest point of a grain boundary, that is, a reduction in the surface roughness of the PZT. This fact matches the measurement results well.

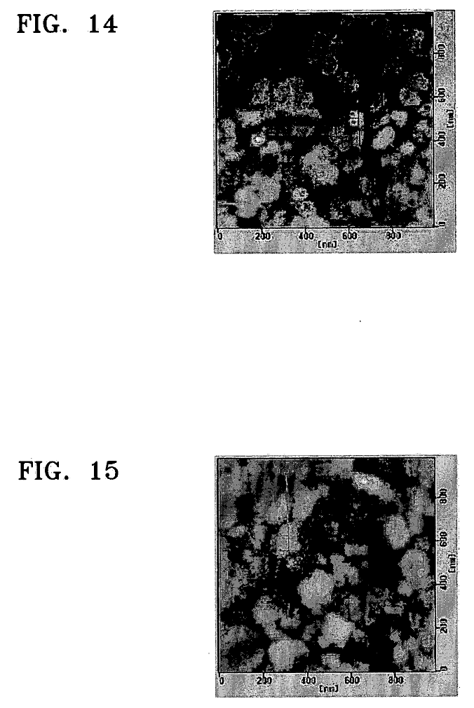

The surface roughness of the PZT film is about 7.03 nm when the PZT film is deposited on a lower electrode composed of Ir only, as shown in FIG. 13. The surface roughness of the PZT film is about 7.33 nm when the PZT film is deposited on a lower electrode composed of only Ir—Pt, as shown in FIGS. 14, 15, and 16. However, the surface roughness of the PZT film decreases to about 4.14 nm when the PZT film is deposited on a lower electrode composed of Pt only, as shown in FIG. 17.

The granular shape of the PZT film illustrated in FIG. 17 is not clear. From the results of the analysis, it was found that the PZT film depicted in FIG. 17 is not in a crystal phase (refer to graph G5 in FIG. 19).

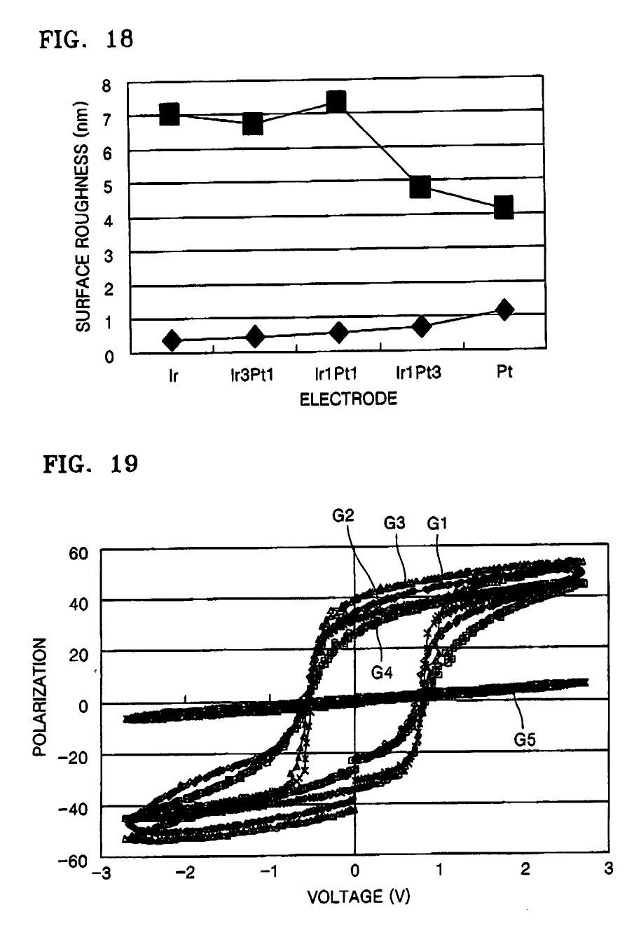

FIG. 18 is a graph illustrating a surface roughness of the lower electrode and the PZT film of the first through fifth capacitors C1 through C5. In FIG. 18, symbol ▪ indicates the surface roughness of the PZT film and symbol ♦ indicates the surface roughness of the lower electrode.

Referring to FIG. 18, it may be seen that as the Pt content of the lower electrode increases, the surface roughness of the lower electrode also increases, but the surface roughness of the PZT film decreases.

FIG. 19 is a graph illustrating hysteresis curves of the first through fifth capacitors C1 through C5.

In FIG. 19, reference symbols G1 through G5 indicate the hysteresis curves of the first through fifth capacitors C1 through C5, respectively.

Referring to the first through fifth curves G1 through G5, a polarization of the third capacitor C3, in which the lower electrode is composed of Ir and Pt in a ratio of 1:1, is the greatest. In the case of the fifth capacitor C5, in which the lower electrode is composed of Pt only, no hysteresis is detected. This result indicates that the PZT film in the fifth capacitor is not in a crystal phase, as noted above.

Table 2 includes the type of lower electrode of each of the capacitors C1 through C5, surface roughness, hysteresis of the capacitors, and whether there is a leakage current from the lower electrode. In Table 2, R1 and R2 indicate the surface roughness of the lower electrode and the PZT film, respectively, 2Pr indicates polarization, and LC indicates whether there is leakage current from the lower electrode.

TABLE 2

| | Type of Lower | | | | |
|---|---|---|---|---|---|
| Capacitor | Electrode | R1 | R2 | 2Pr | LC |
| C1 | Ir | 0.37 | 7.03 | 57.16 | Yes |
| C2 | Ir3Pt1 | 0.46 | 6.69 | 62.27 | Yes |
| C3 | Ir1Pt1 | 0.53 | 7.33 | 73.2 | Yes |
| C4 | Ir1Pt3 | 0.69 | 4.76 | 48.69 | No |
| C5 | Pt | 1.15 | 4.14 | NC | No |

As shown in Table 2, in the lower electrodes having the highest Pt content, there is no leakage current.

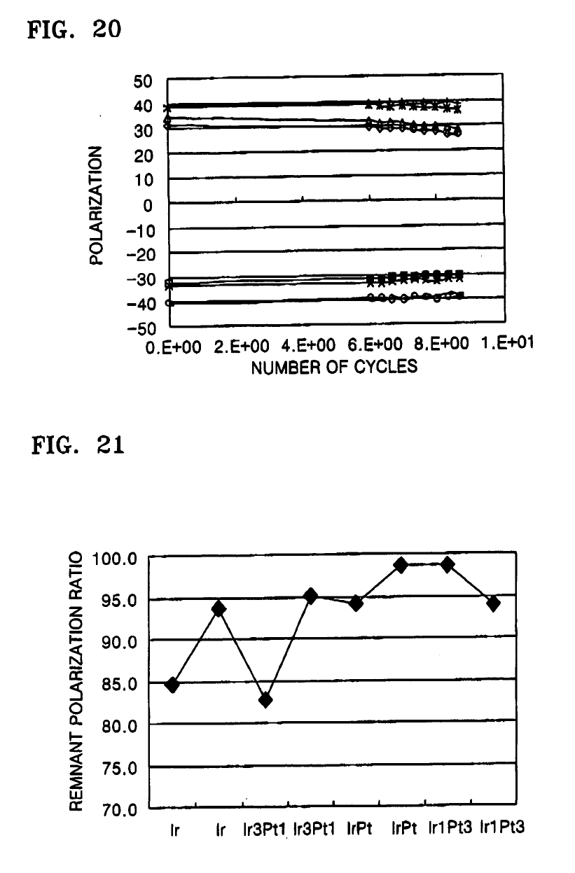

FIG. 20 is a graph illustrating the fatigue of the first through fourth capacitors C1 through C4. In FIG. 20, reference symbols ⋄ and ▪ indicate the fatigue characteristic of the first capacitor C1, reference symbols Δ and x indicate the fatigue characteristics of the second capacitor C2, reference symbols * and o indicate the fatigue characteristics of the third capacitor C3, and reference symbols | and □ indicate the fatigue characteristics of the fourth capacitor C4. The fatigue characteristics of the fifth capacitor C5 are not measured because the fifth capacitor does not show hysteresis, as shown and noted in connection with FIG. 19.

Referring to FIG. 20, as the content of Pt increases, fatigue characteristics improve.

FIG. 21 is a graph illustrating remnant polarization ratios, i.e., (minimum remnant polarization/maximum remnant polarization)×100, of each of the capacitors calculated from the measurement results shown in FIG. 20.

Referring to FIG. 21, the remnant ratios of the second through fourth capacitors C2 through C4 are greater than the remnant ratio of the first capacitor C1.

A method of manufacturing a capacitor according to an embodiment of the present invention will now be described with reference to FIG. 1.

Referring to FIG. 1, the lower electrode 43 is initially formed. The lower electrode 43 may be formed by sequentially stacking the first and second lower electrodes 40 and 42. The first lower electrode 40 may be composed of a predetermined etching-resistive metal, e.g., Ir. The second lower electrode 42 may be composed of an alloy or an alloy oxide, and may be composed of an alloy of a noble metal or a noble metal alloy oxide. When the second lower electrode 42 is composed of a noble metal or a noble metal alloy oxide, the second lower electrode 42 may include an alloy (PtIr) including Iridium (Ir) and platinum (Pt) or an oxide (PtIrOₓ) of the alloy. In this case, the Pt content A is 5%<A<40%, and the value X in the oxide (PtIrOₓ) is 0.5<X≦2.

The lower electrode 43 can be formed using a predetermined deposition apparatus, such as a sputtering apparatus. Since the second lower electrode 42 may be formed of an alloy, a target material for depositing the second lower electrode 42 may be either multiple targets, each an element of the alloy, or a single target that includes all elements of the alloy can be used when sputtering the second lower electrode 42. When the first lower electrode 40 is formed of Ir, a thickness of the first lower electrode 40 may be in a range of between about 30 to about 70 nm. When the second lower electrode 42 is composed of an alloy of Ir and Pt or an alloy oxide, a thickness of the second lower electrode 42 may be in a range of between about 10 to about 30 nm. When the first lower electrode 40 is composed of Ir and the second lower electrode 42 is composed of an alloy of Ir and Pt, the first lower electrode 40 may be omitted.

After forming the lower electrode 43, a dielectric film 44 is formed on the lower electrode 43. The dielectric film 44 may be a ferroelectric film, e.g., a PZT film or a SPT film. The dielectric film 44 may be formed by chemical vapor deposition (CVD), in particular, metal organic CVD (MOCVD), and may also be formed by ALD or sputtering.

When the dielectric film 44 is a PZT film, the dielectric film 44 may be formed to a thickness of between about 30 to about 150 nm by MOCVD. The PZT film may be doped, e.g., with a rare earth element, e.g., lanthanum (La), or a predetermined material, e.g., a silicate, e.g., Bi₂SiO₅ (BSO), may be added to the PZT film.

Next, an upper electrode 49 is formed on the dielectric film 44. The upper electrode 49 may be a single layer or a double layer, e.g., a sequential stack of an Ir layer and an iridium oxide layer.

A method of manufacturing a memory device according to an embodiment of the present invention will now be described with reference to FIG. 2. This method may be divided into operations of forming a transistor on the substrate 50, forming the interlayer insulating layer 60 covering the transistor, and forming on the interlayer insulating layer 60 the capacitor C connected to the transistor. The contact hole 62, through which the drain region 58 of the transistor is exposed, may be formed through the interlayer insulating layer 60. The contact hole 62 may be filled by the conductive plug 64, such as a tungsten plug or a doped polysilicon plug. In addition, the diffusion barrier film 41 can further be formed between the conductive plug 64 and the lower electrode 43 of the capacitor C. The diffusion barrier film 41 may be a TiAlN film, but may also be a TiN film.

As described above, a capacitor according to an embodiment of the present invention may include a lower electrode composed of a Pt—Ir alloy. Since such a lower electrode acts as a strong diffusion barrier, a leakage current can be reduced at an interface between the lower electrode and the PZT film. Since the lower electrode contains Pt, a crystalline nucleus can be easily grown on the lower electrode. Additionally, surface roughness of the PZT film may be reduced by forming the PZT film on the lower electrode composed of a Pt—Ir alloy. Also, since a wide process window of the PZT film can be secured, the PZT film can be formed in a variety of process conditions. As mentioned above, since a leakage current can be reduced due to the lower electrode acting as a strong diffusion barrier, the PZT film may be a thin film. Taking into consideration that a reliability of a capacitor is directly related to leakage current, and reproducibility and yield are directly related to process conditions, a capacitor according to an embodiment of the present invention has improved reliability, reproducibility, and yield. The lower electrode of the capacitor can be composed of a compound of an iridium oxide and platinum. Therefore, the capacitor according to an embodiment of the present invention has improved physical properties, such as a fatigue characteristics and a data storage characteristic.

Exemplary embodiments of the present invention have been disclosed herein, and although specific terms are employed, they are used and are to be interpreted in a generic and descriptive sense only and not for purpose of limitation. For example, one skilled in the art could form the capacitor with a complicated structure, such as a cylindrical structure, as opposed to the simpler stack type capacitor depicted in FIG. 1. Also, one skilled in the art could apply a capacitor according to an embodiment of the present invention to a different memory device other than the memory device illustrated in FIG. 2. Accordingly, it will be understood by those of ordinary skill in the art that various changes in form and details may be made without departing from the spirit and scope of the present invention as set forth in the following claims.

1. A capacitor, comprising:
a lower electrode comprising a single layer of one selected from the group consisting of a noble metal alloy and an oxide thereof;
a dielectric film formed on the lower electrode; and
an upper electrode formed on the dielectric film.

2. The capacitor as claimed in claim 1, further comprising a noble metal layer, on which the lower electrode is formed.

3. The capacitor as claimed in claim 2, wherein the noble metal layer is an iridium layer.

4. The capacitor as claimed in claim 2, wherein the lower electrode comprises an alloy including platinum and iridium, and a thickness of the lower electrode is in a range of between about 10 to about 30 nm.

5. The capacitor as claimed in claim 1, wherein the lower electrode comprises an alloy including platinum and iridium.

6. The capacitor as claimed in claim 1, wherein the dielectric film is a PZT film.

7. The capacitor as claimed in claim 6, wherein the PZT film comprises one selected from the group consisting of a rare earth element and a silicate.

8. The capacitor as claimed in claim 1, wherein the lower electrode comprises an alloy including platinum and iridium, and a thickness of the lower electrode is in a range of between about 10 to about 100 nm.

9. The capacitor as claimed in claim 1, wherein the lower electrode comprises an oxide of an alloy including platinum and iridium.

10. A memory device, comprising:
a substrate;
a transistor formed on the substrate; and
a capacitor connected to the transistor,
wherein the capacitor includes
a lower electrode comprising a single layer of one selected from the group consisting of a noble metal alloy and an oxide thereof;
a dielectric film formed on the lower electrode; and
an upper electrode formed on the dielectric film.

11. The memory device as claimed in claim 10, wherein the noble metal alloy comprises platinum and iridium.

12. The memory device as claimed in claim 10, wherein the noble metal alloy oxide comprises an oxide of an alloy including platinum and iridium.

13. The memory device as claimed in claim 10, further comprising a noble metal layer, on which the lower electrode is formed.

14. The memory device as claimed in claim 13, wherein the noble metal layer is an iridium layer.

15. The memory device as claimed in claim 10, further comprising:
a connection means for connecting the capacitor to the transistor; and
a diffusion barrier film interposed between the connection means and the lower electrode.

16. The memory device as claimed in claim 15, wherein the diffusion barrier film is selected from the group consisting of a TiAlN film and a TiN film.

17. A method of manufacturing a capacitor, comprising:
forming a lower electrode comprising a single layer of one selected from the group consisting of a noble metal alloy and an oxide thereof; and
sequentially stacking a dielectric film and an upper electrode on the lower electrode.

18. The method as claimed in claim 17, further comprising forming the lower electrode on a noble metal layer.

19. The method as claimed in claim 17, wherein the dielectric film is a PZT film.

20. The method as claimed in claim 19, wherein forming the PZT film comprises using one of chemical vapor deposition (CVD), atomic layer deposition (ALD), and sputtering.

21. The method as claimed in claim 19, further comprising doping the PZT film with a rare earth element.

22. The method as claimed in claim 19, further comprising adding a silicate to the PZT film.

23. The method as claimed in claim 17, wherein forming the lower electrode comprises using multi-targets or an alloy target.

24. The method as claimed in claim 17, wherein the noble metal alloy comprises platinum and iridium.

25. The method as claimed in claim 17, wherein forming the lower electrode further comprises forming a noble metal alloy and oxidizing the noble metal alloy.
